(19) United States
(12) Patent Application Publication
(10) Pub. No.: US 2025/0364486 A1
(43) Pub. Date: Nov. 27, 2025

(54) LATERAL SILICON BRIDGE FOR STACKED DIES

(71) Applicant: Advanced Micro Devices, Inc., Santa Clara, CA (US)

(72) Inventors: Raja Swaminathan, Austin, TX (US); Chandra Sekhar Mandalapu, Fort Collins, CO (US); Liwei Wang, Fort Collins, CO (US); John Wuu, Fort Collins, CO (US)

(73) Assignee: Advanced Micro Devices, Inc., Santa Clara, CA (US)

(21) Appl. No.: 18/179,858

(22) Filed: Mar. 7, 2023

(51) Int. Cl. H01L 25/065; H01L 23/00; H01L 25/00

(52) U.S. Cl. CPC H01L 25/0652; H01L 24/05; H01L 24/08; H01L 24/80; H01L 25/0657; H01L 25/50; H01L 2224/0557; H01L 2224/08145; H01L 2224/08225; H01L 2224/80006; H01L 2224/80896; H01L 2225/06548

(57) ABSTRACT

The disclosed device includes a bottom die layer having a bottom die and a bridge die adjacent to the bottom die. The device also includes a top die layer positioned on the bottom die layer and having a top die overlying at least a portion of the bottom die and overlying at least a portion of the bridge die. Various other methods, systems, and computer-readable media are also disclosed.

### BACKGROUND

System-on-integrated-chip (SolC) and other three-dimensional (3D) chip architectures integrate active and passive chips into a system-on-chip (SoC) system to provide higher functionality packaging density, reduced communication latency, and reduced energy consumption to improve computing efficiency. 3D architectures allow, for example, logic-on-logic or memory-on-logic chiplet stacking to allow integration of different chip sizes, functionalities and/or wafer node technologies into a single platform. Chiplets on an upper layer can require connections through layers thereunder.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a diagram of an exemplary 3D chip.

FIG. 2 is a diagram of an exemplary 3D chip with a bridge die.

FIGS. 3A-3D are diagrams of exemplary layouts for bridge dies.

FIG. 4 is a flow diagram of an exemplary method for fabricating a 3D chip with a bridge die.

FIGS. 5A-5F are diagrams of exemplary steps for fabricating a 3D chip with a bridge die.

Throughout the drawings, identical reference characters and descriptions indicate similar, but not necessarily identical, elements. While the exemplary implementations described herein are susceptible to various modifications and alternative forms, specific implementations have been shown by way of example in the drawings and will be described in detail herein. However, the exemplary implementations described herein are not intended to be limited to the particular forms disclosed. Rather, the present disclosure covers all modifications, equivalents, and alternatives falling within the scope of the appended claims.

### DETAILED DESCRIPTION

The present disclosure is generally directed to lateral silicon bridge dies for stacked dies. As will be explained in greater detail below, implementations of the present disclosure provide for bridge dies placed laterally to a bottom die of a stacked die structure having a larger top die over the bottom die. The bridge dies can provide support for the larger top die as well as provide interconnects (e.g., through-silicon vias (TSVs)). In some implementations, the bridge dies are components. The systems and methods described herein can improve thermal performance and allow for architectures having smaller bottom dies compared to top dies. Additionally, the systems and methods herein can improve fabrication for example by avoiding process challenges for through-dielectric vias (TDVs) and improving yield by using known good dies (KGD) during a stacking process.

As will be described in greater detail below, the instant disclosure describes various systems and methods for placing bridge dies laterally to a bottom die of a stacked die structure. A device can have a bottom die layer and a top die layer thereover. The bottom die layer can include a bottom die and a bridge die that supports a top die in the top die layer.

In one implementation, a device includes a bottom die layer and a top die layer. The bottom die layer includes a bottom die and a bridge die adjacent to the bottom die. The top die layer is positioned on the bottom die layer and includes a top die overlying at least a portion of the bottom die and overlying at least a portion of the bridge die.

In some examples, the bridge die includes an interconnect extending through the bridge die and coupled to the top die. In some examples, the interconnect corresponds to a through-silicon via (TSV). In some examples, an area of the top die exceeds an area of the bottom die. In some examples, sidewalls of the top die extend beyond the bottom die and the bridge die. In some examples, the top die layer is hybrid bonded to the bottom die layer.

In some examples, the bridge die corresponds to a passive device die. In some examples, the bridge die corresponds to an active device die. In some examples, the bridge die comprises a silicon structure. In some examples, the bottom die layer includes a plurality of bridge dies adjacent to the bottom die.

In one implementation, a system for a 3D chip with a bridge die includes a substrate, a first die tier positioned on the substrate, and a second die tier. The first die tier includes a bottom die and a bridge die adjacent to the bottom die and includes an interconnect extending through the bridge die. The second die tier is positioned on the first die tier and includes a top die overlying at least a portion of the bottom die and overlying at least a portion of the bridge die. The top die is coupled to the substrate via the interconnect.

In some examples, the interconnect corresponds to a through-silicon via (TSV). In some examples, an area of the top die exceeds an area of the bottom die. In some examples, sidewalls of the top die extend beyond the bottom die and the bridge die. In some examples, the top die is hybrid bonded to the bottom die.

In some examples, the bridge die corresponds to a passive device die. In some examples, the bridge die corresponds to an active device die. In some examples, the bridge die comprises a silicon structure. In some examples, the first die tier includes a plurality of bridge dies adjacent to the bottom die.

In one example, a method for fabricating a 3D chip with a bridge die includes (i) attaching, to a carrier wafer, a first die tier comprising a bottom die and a bridge die, (ii) creating an interconnect through the bridge die, (iii) bonding, to the first die tier, a second die tier comprising a top die, and (iv) removing the carrier wafer.

In some examples, the method also includes coupling the top die to the interconnect. In some examples, method further includes attaching a second carrier wafer to the second die tier. In some examples, bonding the second die tier to the first die tier includes hybrid bonding the second die tier to the first die tier.

Features from any of the implementations described herein can be used in combination with one another in accordance with the general principles described herein. These and other implementations, features, and advantages will be more fully understood upon reading the following detailed description in conjunction with the accompanying drawings and claims.

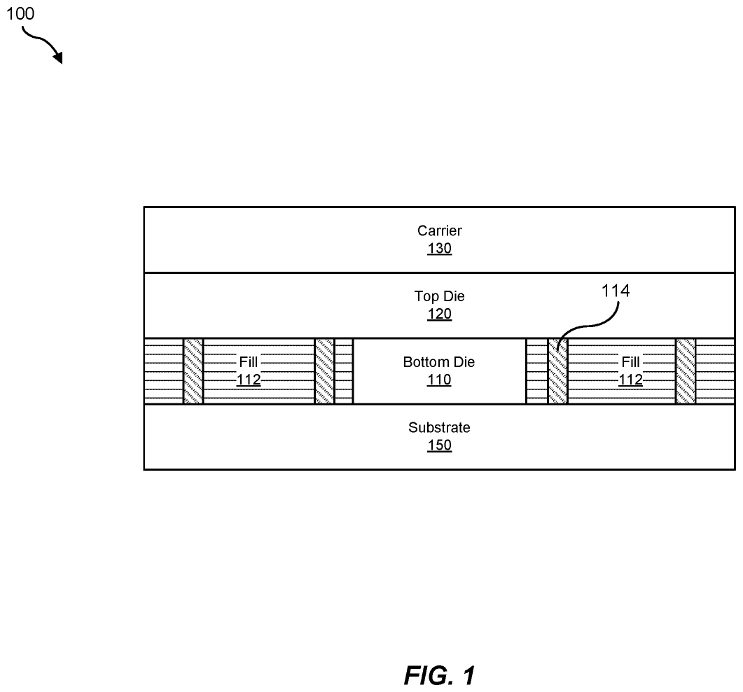

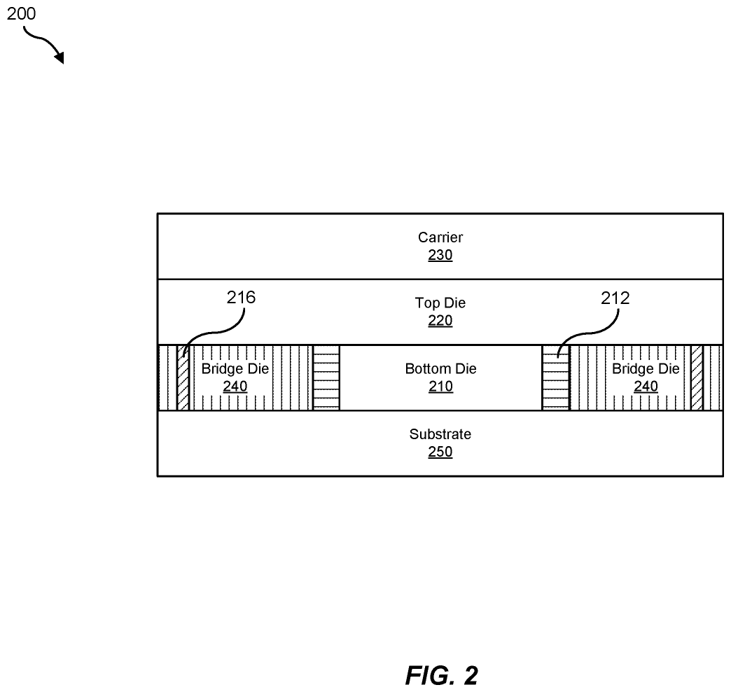

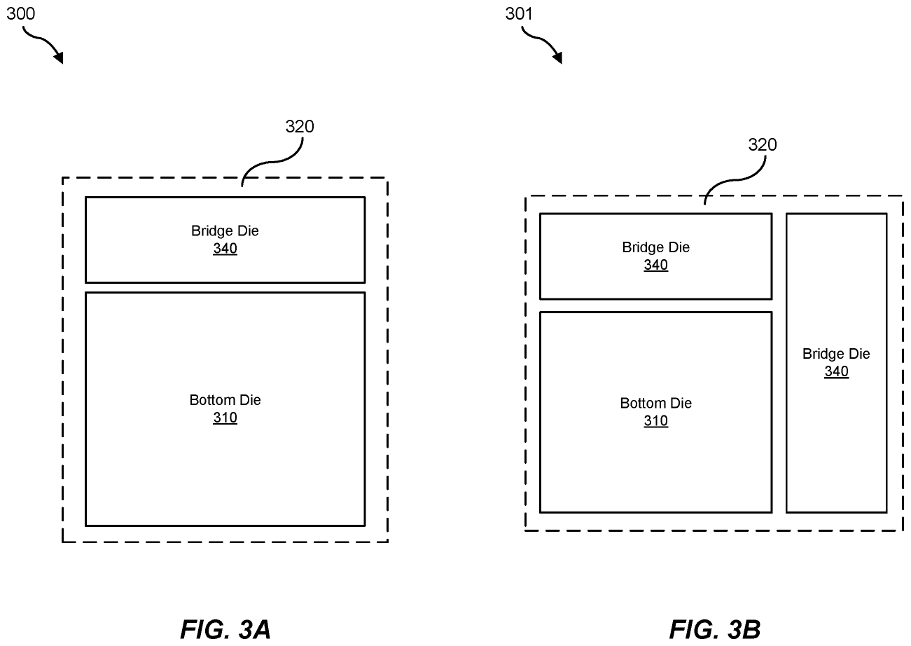

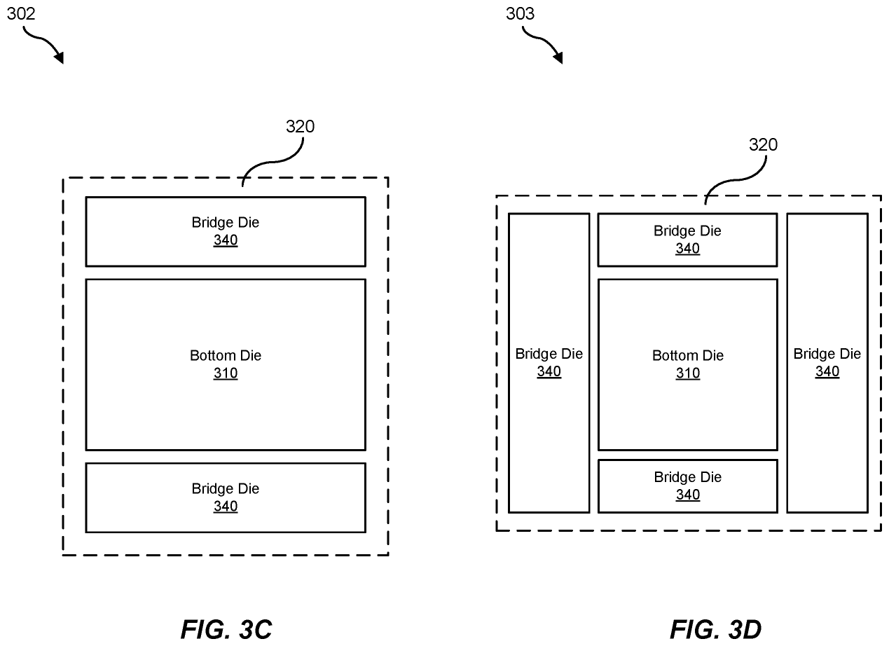

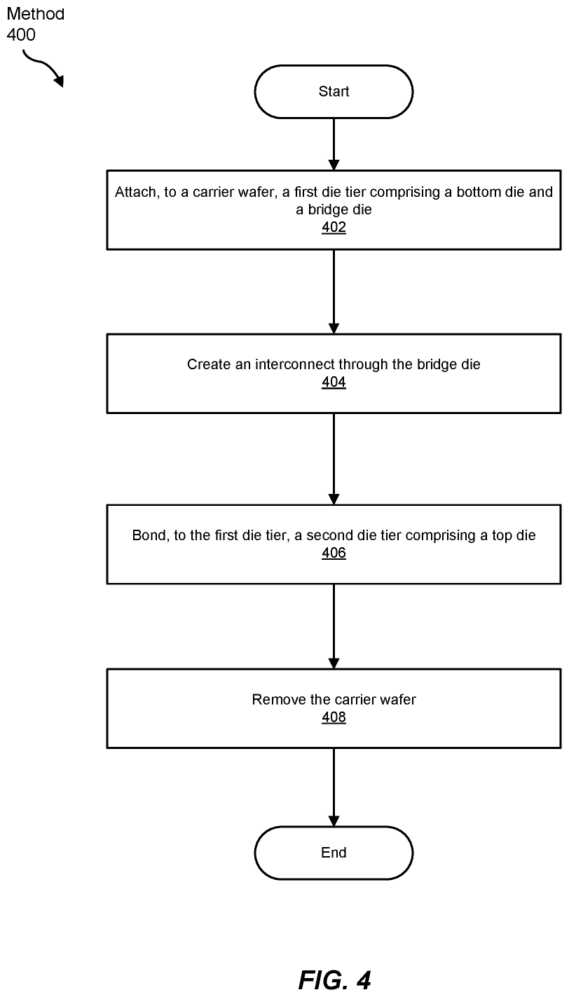

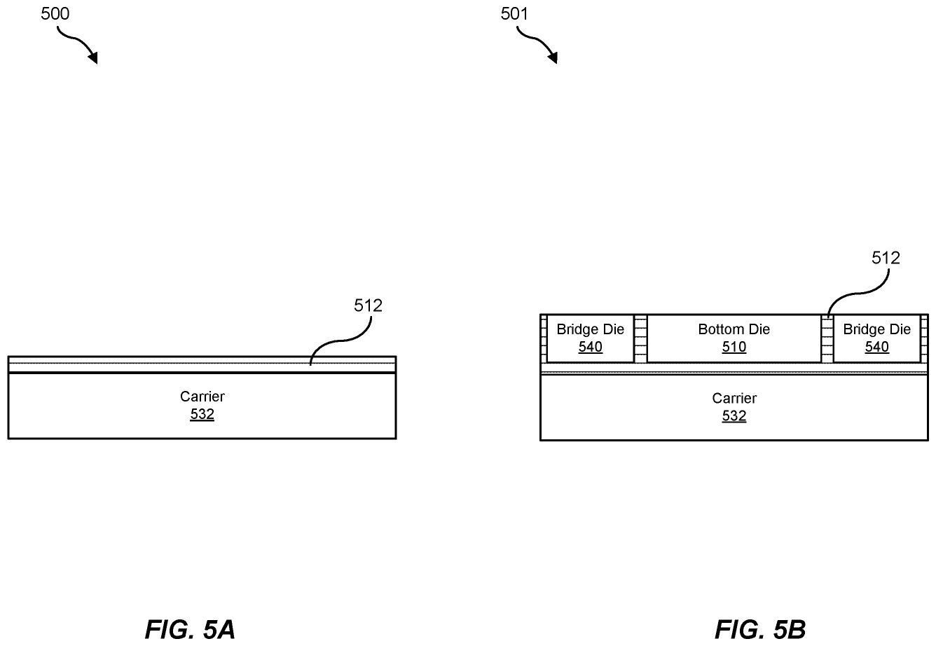

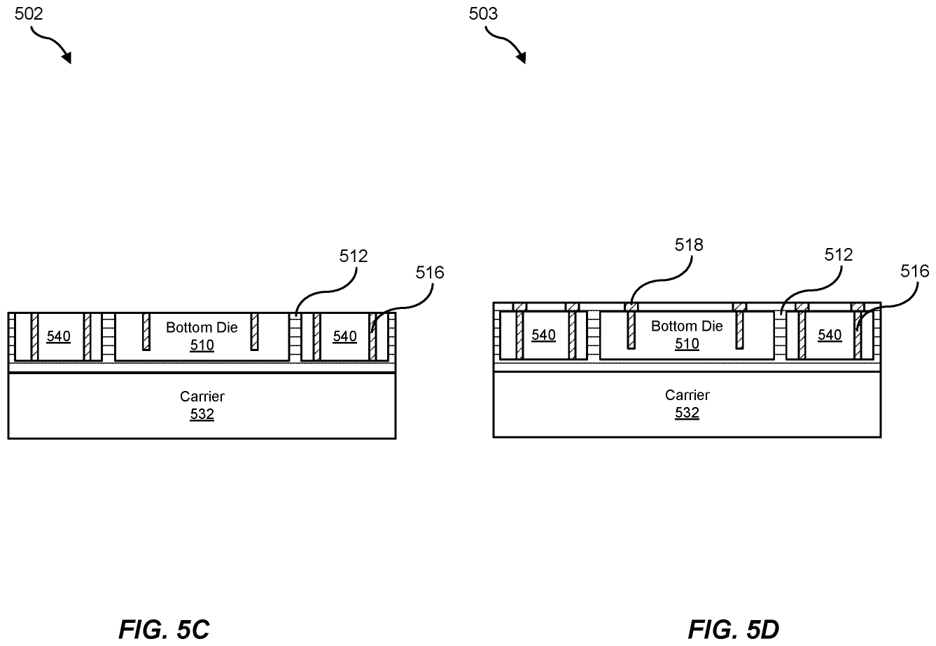

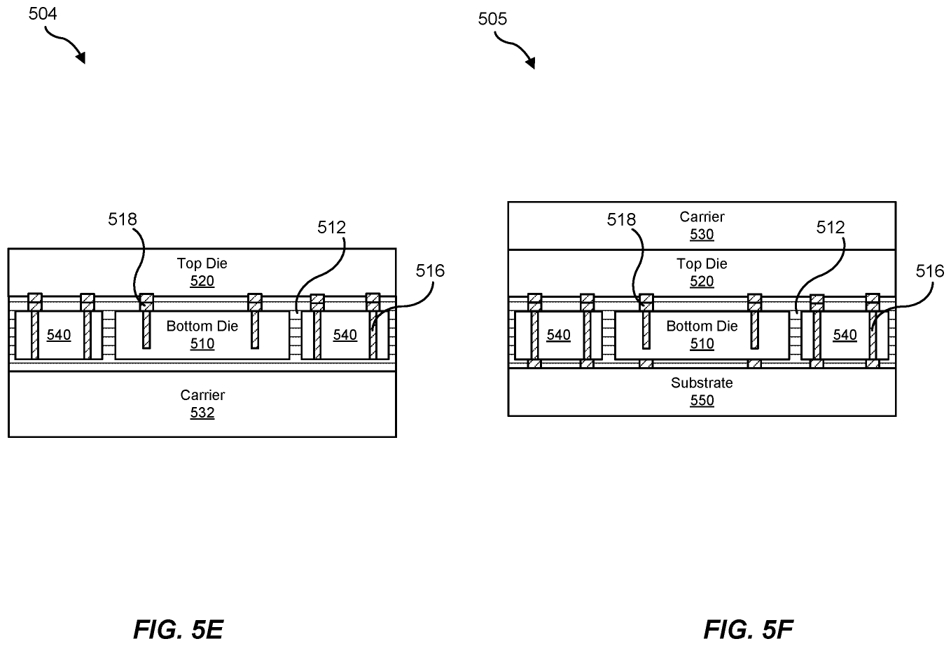

The following will provide, with reference to FIGS. 1-5E, detailed descriptions of 3D chips with bridge dies along with example fabrication steps. Detailed descriptions of example 3D chips will be provided in connection with FIG. 1. Detailed descriptions of variations of 3D chips with bridge dies will be provided in connection with FIGS. 2-3D. Detailed descriptions of corresponding fabrication methods and stages will also be provided in connection with FIGS. 4-5F.

FIG. 1 illustrates a cut away side view of a device 100 having an example SolC architecture, chiplet architecture, or other 3D chip architecture. Device 100 includes a substrate 150, a bottom die layer over substrate 150, and a top die layer over the bottom die layer. The bottom die layer includes a bottom die 110, a fill 112, and one or more interconnects 114. The top die layer includes top die 120. Device 100 also includes a carrier wafer 130. Carrier wafer 130, which in some examples is made of silicon, glass, or other material, can provide structural support particularly during fabrication of device 100, although in some examples may be removed or reduced.

Bottom die 110 correspond to various types of chiplets, such as processors, microprocessors, logic units, and/or any other component. Although only one bottom die is illustrated in FIG. 1, in other examples the bottom die layer can include additional bottom dies laterally offset from bottom die 110 with fill 112 therebetween. Moreover, in other examples, bottom die 110 can take on various other shapes, sizes, etc. The bottom die layer is positioned on substrate 150, which can correspond to a circuit board or any other surface for mounting chiplets.

The top die layer includes top die 120 that correspond to various chiplets, such as memory devices, logic units, and/or any other component. Although FIG. 1 illustrates a single top die, in some examples, the top die layer can include additional top dies, and the top dies can take on various other shapes, sizes, etc. As shown in FIG. 1, the top die layer (e.g., top die 120) is stacked onto the bottom die layer such that top die 120 can be directly mounted onto and/or directly bonded (and/or hybrid bonded) to bottom die 110, although in some examples there can be one or more interleaving layers therebetween.

As further illustrated in FIG. 1, top die 120 is larger than (e.g., has a greater planar surface area than) bottom die 110 such that top die 120 can overhang bottom die 110. Fill 112, such as an oxide or an adhesive, can provide structural support, isolation, etc, particularly in areas where top die 120 is not supported by bottom die 110. Although not illustrated in FIG. 1, top die 120 is electrically connected to bottom die 110. Top die 120 is also electrically connected to substrate 150 through one or more interconnects 114.

In some implementations, the term “interconnect” can refer to any type of electrically conductive structure and/or material for electrically coupling components. Examples of interconnects include, without limitation, through-silicon vias (TSVs), through-dielectric vias (TDVs), pads, bumps, traces, etc. In some examples, an interconnect can extend vertically through and/or laterally through a die or other structure.

In FIG. 1, in order to couple top die 120 to substrate 150, interconnect 114 extends though fill 112. Accordingly, interconnect 114 can correspond to a TDV. However, fabricating TDVs can provide challenges to a fabrication process. In addition, fill 112 can provide poor thermal performance (e.g., poor thermal conductivity for dissipating heat).

FIG. 2 illustrates a cut away side view of a device 200 having an example SolC architecture, chiplet architecture, or other 3D chip architecture. Device 200 includes a substrate 250, a bottom die layer over substrate 250, and a top die layer over the bottom die layer. The bottom die layer includes a bottom die 210, one or more bridge dies 240 positioned adjacent and laterally to bottom die 210, and a fill 212 therebetween. The top die layer includes top die 220. Device 200 also includes a carrier wafer 230. Carrier wafer 230, which in some examples is made of silicon, glass, or other material, can provide structural support particularly during fabrication of device 200, although in some examples may be removed or reduced.

Bottom die 210 correspond to various types of chiplets, such as processors, microprocessors, logic units, and/or any other component. Although only one bottom die is illustrated in FIG. 2, in other examples the bottom die layer can include additional bottom dies laterally offset from bottom die 210 with fill 212 therebetween. Moreover, in other examples, bottom die 210 can take on various other shapes, sizes, etc. The bottom die layer is positioned on substrate 250, which can correspond to a circuit board or any other surface for mounting chiplets.

The top die layer includes top die 220 that correspond to various chiplets, such as memory devices, logic units, and/or any other component. Although FIG. 2 illustrates a single top die, in some examples, the top die layer can include additional top dies, and the top dies can take on various other shapes, sizes, etc. As shown in FIG. 2, the top die layer (e.g., top die 220) is stacked onto the bottom die layer such that top die 220 can be directly mounted onto and/or directly bonded (and/or hybrid bonded) to bottom die 210, although in some examples there can be one or more interleaving layers therebetween.

As further illustrated in FIG. 2, top die 220 is larger than (e.g., has a greater planar surface area than or otherwise exceeds an area of) bottom die 210 such that top die 220 can overhang bottom die 210. However, in contrast to FIG. 1, top die 220 can be supported by bridge die 240. Although fill 212, such as an oxide or an adhesive, can provide some structural support, isolation, etc., in some implementations fill 212 can be removed. Bridge die 240 can correspond to a silicon or other semiconductor structure and in some implementations can correspond to an active and/or passive device or component. In addition, in other examples device 200 can include more or fewer bridge dies 240.

Although not illustrated in FIG. 2, top die 220 is electrically connected to bottom die 210. Top die 220 is also electrically connected to substrate 250 through one or more interconnects 216. In contrast to interconnect 114 in FIG. 1, interconnect 216 extends through silicon (e.g., through a thickness of bridge die 240). Accordingly, interconnect 216 can correspond to a TSV, which can be less challenging to fabricate than a TDV. In addition, bridge die 240 provides better thermal performance than fill 212.

FIGS. 3A-3D illustrate, respectively, top-down views of a device 300, a device 301, a device 302, and a device 303 that can each correspond to examples of device 200. The top-down views illustrate a bottom die 310 that corresponds to bottom die 210, a bridge die 340 that corresponds to bridge die 240, and a top die 320 that corresponds to top die 220. In FIGS. 3A-3D, top die 320 is illustrated as an outline in order to show the dies thereunder.

In FIG. 3A, bridge die 340 is adjacent and lateral to one side of bottom die 310. In FIG. 3B, bridge dies 340 are positioned along two connecting or adjacent sides of bottom die 310. In FIG. 3C, bridge dies 340 are positioned along two opposite sides of bottom die 310. In FIG. 3D, bridge dies 340 are positioned along all four sides of bottom die 310. In other examples, other configurations are possible (e.g., removing one bridge die 340 from FIG. 3D such that bridge dies 340 are along three sides of bottom die 310, etc.).

FIGS. 3A-3D show various example configurations that can be combined and/or repeated. In addition, although FIGS. 3A-3D illustrate top die 320 completely covering bottom die 310 and bridge die 340 thereunder (e.g., such that sidewalls of top die 320 extend beyond bottom die 310 and bridge die 340), in other examples top die 320 can partially cover bottom die 310 and/or bridge die 340.

FIG. 4 is a flow diagram of an exemplary computer-implemented method 400 for fabricating a 3D chip with a bridge die. The steps shown in FIG. 4 can be performed by using any suitable chip fabrication systems and/or techniques and performed and/or repeated in any order as needed. The steps shown in FIG. 4 are further explained in reference to FIGS. 5A-5F, which illustrate example fabrication stages.

As illustrated in FIG. 4, at step 402 one or more of the systems described herein attaches, to a carrier wafer, a first die tier comprising a bottom die and a bridge die. The systems described herein can perform step 402 in a variety of ways. In one example, shown in stage 500 in FIG. 5A, a carrier 532 (which can correspond to an iteration of carrier wafer 230) can be prepared and in stage 501 in FIG. 5B, a bottom die layer can be attached to carrier 532. The bottom die layer can include one or more bridge dies 540 (each corresponding to iterations of bridge die 240), a bottom die 510 (corresponding to bottom die 210), and a fill 512 (corresponding to fill 212).

In some implementations, the bottom die layer can be bonded to carrier 532 using fusion bond, although in other implementations other attachment processes can be used. Further, in some implementations, the bottom die layer can be processed, such as backside processing (e.g., revealing interconnects), preparation for hybrid bonding (e.g., preparing for attaching a top die layer), etc.

Returning to FIG. 4, at step 404 one or more of the systems described herein creates an interconnect through the bridge die. For example, at stage 502 in FIG. 5C, one or more interconnects 516 (each corresponding to iterations of interconnect 216), can be formed, extending through bridge die 540. For example, TSVs can be formed in bridge die 540 and/or bottom die 510 as needed.

In some implementations, interconnects 516 can be formed before attaching the bottom die layer to carrier 532. For example, TSVs can be formed in bridge die 540 and/or bottom die 510 and the resulting bottom die layer can be attached to carrier 532.

At stage 503 in FIG. 5, contacts 518 (e.g., bumps and/or other electrical connection points) are created for connecting to interconnects 516. Contacts 518 allow a top die layer to connect to interconnects 516 to further couple to components as needed.

Turning back to FIG. 4, at step 406 one or more of the systems described herein bonds, to the first die tier (e.g., the bottom die layer), a second die tier (e.g., the top die layer) comprising a top die. For example, at stage 504 in FIG. 5E, top die 520 is attached to the bottom die layer. Although not illustrated, the top die layer is prepared for hybrid bonding.

In some implementations, top die 520 is coupled to interconnects 516, as illustrated in FIG. 5E. In some implementations, a second carrier wafer (e.g., carrier 530 in FIG. 5F) is attached to the top die tier, such as though wafer-on-wafer bonding.

At step 408 in FIG. 4, one or more of the systems described herein removes the carrier wafer (e.g., carrier 532), as illustrated in stage 505 in FIG. 5F. In some implementations, the stack can be bumped and diced, and the stacked dies can go to downstream packaging (e.g., mounting onto a substrate 550 in FIG. 5F). As illustrated in FIG. 5F, interconnects 516 allow top die 520 to be coupled to substrate 550. Further, in some implementations additional die tiers or layers can be added.

As detailed above, the present disclosure provides lateral silicon bridges to connect a top die to a substrate/interposer/wafer-level fan out (WLFO) (depending on the architecture) in addition to the connections between top die and bottom die using different types of bonding. This can allow chiplet architectures having a small bottom die compared to top die size.

The described process flow allows chiplet architectures with smaller bottom die compared to the top die. For example, the process flow can include: (A) preparing a Tier1 wafer: Bottom dies and Silicon bridge (SiB) dies are bonded to a carrier1 (C1) wafer using fusion bond. (B) Preparing a Tier2 wafer: a large top die surface is prepared for hybrid bonding. (C) A top die is hybrid bonded to the backside of a bottom die and silicon bridge die. (D) Carrier 2 Wafer-on-Wafer bonding: a C2 wafer is attached to the top die. (E) C1 is removed, followed by bumping and dicing of the dies. (F) Depending on the architecture, the stacked dies are sent to downstream packaging and ab assembly process. (G) This process is extendable to a 2-high stack if needed.

The proposed solution enables chiplet architectures with smaller bottom dies compared to the top die using different bonding techniques. By utilizing the lateral silicon bridge to connect the top die signal and power routing to the downstream packaging process (Si interposer/WLFO, or substrate) in addition to the signal routing connections between bottom and top dies, more IO density at a given Si area can be achieved. In addition, this architecture has more Si area for better thermal conductivity compared to filling with oxide and using TDVs. Moreover, processing of smaller silicon bridge (SiB) dies with oxide surface can be easier to manage than Cu hybrid bonding surface, allowing higher yields during the stacking process.

As detailed above, the computing devices and systems described and/or illustrated herein broadly represent any type or form of computing device or system capable of executing computer-readable instructions, such as those contained within the modules described herein. In their most basic configuration, these computing device(s) each include at least one memory device and at least one physical processor.

In some examples, the term “memory device” generally refers to any type or form of volatile or non-volatile storage device or medium capable of storing data and/or computer-readable instructions. In one example, a memory device stores, loads, and/or maintains one or more of the modules and/or circuits described herein. Examples of memory devices include, without limitation, Random Access Memory (RAM), Read Only Memory (ROM), flash memory, Hard Disk Drives (HDDs), Solid-State Drives (SSDs), optical disk drives, caches, variations, or combinations of one or more of the same, or any other suitable storage memory.

In some examples, the term “physical processor” generally refers to any type or form of hardware-implemented processing unit capable of interpreting and/or executing computer-readable instructions. In one example, a physical processor accesses and/or modifies one or more modules stored in the above-described memory device. Examples of physical processors include, without limitation, microprocessors, microcontrollers, Central Processing Units (CPUs), Field-Programmable Gate Arrays (FPGAs) that implement softcore processors, Application-Specific Integrated Circuits (ASICs), systems on a chip (SoCs), digital signal processors (DSPs), Neural Network Engines (NNEs), accelerators, graphics processing units (GPUs), portions of one or more of the same, variations or combinations of one or more of the same, or any other suitable physical processor.

In some implementations, the term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The process parameters and sequence of the steps described and/or illustrated herein are given by way of example only and can be varied as desired. For example, while the steps illustrated and/or described herein are shown or discussed in a particular order, these steps do not necessarily need to be performed in the order illustrated or discussed. The various exemplary methods described and/or illustrated herein can also omit one or more of the steps described or illustrated herein or include additional steps in addition to those disclosed.

The preceding description has been provided to enable others skilled in the art to best utilize various aspects of the exemplary implementations disclosed herein. This exemplary description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A device comprising:
a bottom die layer comprising a bottom die and a bridge die adjacent to the bottom die; and
a top die layer positioned on the bottom die layer and comprising a top die overlying at least a portion of the bottom die and overlying at least a portion of the bridge die.

2. The device of claim 1, wherein the bridge die includes an interconnect extending through the bridge die and coupled to the top die.

3. The device of claim 2, wherein the interconnect corresponds to a through-silicon via (TSV).

4. The device of claim 1, wherein an area of the top die exceeds an area of the bottom die and sidewalls of the top die extend beyond the bottom die and the bridge die.

5. The device of claim 1, wherein the top die layer is hybrid bonded to the bottom die layer.

6. The device of claim 1, wherein the bridge die corresponds to a passive device die.

7. The device of claim 1, wherein the bridge die corresponds to an active device die.

8. The device of claim 1, wherein the bridge die comprises a silicon structure.

9. The device of claim 1, wherein the bottom die layer comprises a plurality of bridge dies adjacent to the bottom die.

10. A system comprising:
a substrate;
a first die tier positioned on the substrate and comprising:
a bottom die; and
a bridge die adjacent to the bottom die and comprising an interconnect extending through the bridge die; and
a second die tier positioned on the first die tier and comprising a top die overlying at least a portion of the bottom die and overlying at least a portion of the bridge die, the top die coupled to the substrate via the interconnect.

11. The system of claim 10, wherein the interconnect corresponds to a through-silicon via (TSV).

12. The system of claim 10, wherein an area of the top die exceeds an area of the bottom dieand sidewalls of the top die extend beyond the bottom die and the bridge die.

13. The system of claim 10, wherein the top die is hybrid bonded to the bottom die.

14. The system of claim 10, wherein the bridge die corresponds to a passive device die.

15. The system of claim 10, wherein the bridge die corresponds to an active device die.

16. The system of claim 10, wherein the bridge die comprises a silicon structure.

17. The system of claim 10, wherein the first die tier comprises a plurality of bridge dies adjacent to the bottom die.

18. A method comprising:
attaching, to a carrier wafer, a first die tier comprising a bottom die and a bridge die;
creating an interconnect through the bridge die;
bonding, to the first die tier, a second die tier comprising a top die; and
removing the carrier wafer.

19. The method of claim 18, further comprising coupling the top die to the interconnect.

20. The method of claim 18, wherein bonding the second die tier to the first die tier further comprises hybrid bonding the second die tier to the first die tier.
